(19) United States
(12) Patent Application Publication
(10) Pub. No.: US 2024/0213173 A1
(43) Pub. Date: Jun. 27, 2024

(54) ALIGNMENT PATTERN HAVING AN E SHAPE

(71) Applicant: Micron Technology, Inc., Boise, ID (US)

(72) Inventor: Chinaru Takahashi, Higashihiroshima (JP)

(73) Assignee: Micron Technology, Inc., Boise, ID (US)

(21) Appl. No.: 18/481,133

(22) Filed: Oct. 4, 2023

Related U.S. Application Data
(60) Provisional application No. 63/476,603, filed on Dec. 21, 2022.

(51) Int. Cl. H01L 23/544

(52) U.S. Cl. CPC H01L 23/544; H01L 2223/54426

(57) ABSTRACT

An apparatus includes an alignment pattern which comprises: a first line portion of a first material extending in a first direction; a second line portion of the first material extending in the first direction in parallel to the first line portion; a third line portion of the first material extending in a second direction perpendicular to the first direction such that the third line portion connects an edge of the first line portion and an edge of the second line portion; and a fourth line portion of a second material arranged between the first line portion and the second line portion and extending in the first direction.

### CROSS REFERENCE TO RELATED APPLICATION(S)

This application claims priority to U.S. Provisional Application No. 63/476,603, filed Dec. 21, 2022. The aforementioned application is incorporated herein by reference, in its entirety, for any purpose.

### BACKGROUND

In ultra-large-scale integration (ULSI) and other semiconductor devices, pattern lengths may be measured using a critical dimension-scanning electron microscope (CD-SEM) in some cases to check the integrity and the like of patterns formed on a semiconductor substrate (wafer) during the manufacturing process. To confirm the positions of the length measurement locations, it is necessary to confirm the origin positions of a plurality of shots provided on the wafer. For this reason, an alignment mark is provided for each shot on the wafer. By measuring the position of the alignment mark with the CD-SEM, the origin position and the length measurement location of each shot are confirmed.

### BRIEF DESCRIPTION OF THE DRAWINGS

FIG. 1 is a plan view illustrating a schematic configuration of an alignment mark according to an embodiment.

FIG. 2 is a diagram illustrating a schematic configuration of an alignment mark according to the embodiment. FIG. 2 is a longitudinal section illustrating the schematic configuration of a portion along the line A-A in FIG. 1.

FIG. 3 is a plan view illustrating an example of a shot arrangement according to the embodiment.

FIG. 4 is a plan view illustrating an example of the placement of an alignment mark according to the embodiment.

FIG. 5 is a plan view illustrating an example of the placement of an alignment mark according to the embodiment.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessary mutually exclusive, as some disclosed embodiments can be combined with one or more other disclosed embodiments to form new embodiments.

Hereinafter, an alignment mark (alignment pattern) M according to the embodiment will be described with reference to the drawings. In the following description, common or related elements and elements that are substantially the same are denoted with the same signs, and the description thereof will be reduced or omitted. In the drawings referenced hereinafter, the dimensions and dimensional ratios of each unit in each of the drawings do not necessarily match the actual dimensions and dimensional ratios in the embodiment. Furthermore, in the following description, the Y direction is perpendicular to the X direction. Also, the Z direction is the direction perpendicular to the X-Y plane defined as the plane of a semiconductor substrate, and is also referred to as the vertical direction.

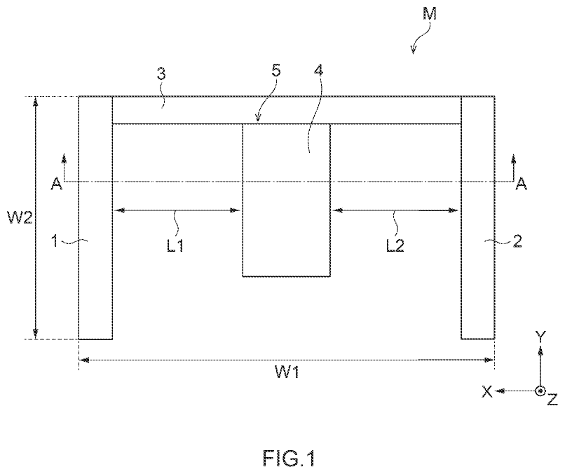

Hereinafter, the alignment mark M according to the embodiment will be described. As illustrated in FIG. 1, the alignment mark M is provided with an E shape rotated 90 degrees to the right in a planar view. The alignment mark M is placed in each shot of a plurality of shots provided on a semiconductor substrate. Specific examples of placement locations will be described later.

The alignment mark M is provided with a first line portion 1, a second line portion 2, a third line portion 3, and a fourth line portion 4. The first line portion 1 and the second line portion 2 each have a rectangular or oblong shape of predetermined width and length. The longitudinal direction of the first line portion 1 and the second line portion 2 is the Y direction in FIG. 1. The first line portion 1 and the second line portion 2 have the same width and the same length. The first line portion 1 and the second line portion 2 have a predetermined spacing and are arranged in parallel.

The third line portion 3 has the same width as the first line portion 1 and the second line portion 2. The third line portion 3 has a rectangular or oblong shape of the same or a different length from the first line portion 1 and the second line portion 2. The longitudinal direction of the third line portion 3 is the X direction in FIG. 1. In FIG. 1, boundary lines are drawn between the third line portion 3 and each of the first line portion 1 and the second line portion 2, but in actuality, there are no boundary lines between the first line portion 1, the second line portion 2, and the third line portion 3, and these portions are provided in an integrally connected manner.

The fourth line portion 4 has a rectangular or oblong shape of predetermined width and length. The longitudinal direction of the fourth line portion 4 is the Y direction in FIG. 1. The fourth line portion 4 has a width that is wider than the first line portion 1 and the second line portion 2, and has a length that is shorter than the first line portion 1 and the second line portion 2. The fourth line portion 4 is arranged between the first line portion 1 and the second line portion 2, and contacting the third line portion 3 at a boundary 5. In FIG. 1, the distance L1 between the first line portion 1 and the fourth line portion 4 and the distance L2 between the second line portion 2 and the fourth line portion 4 are substantially the same, but may also be different.

The third line portion 3 is connected to the first line portion 1, the second line portion 2, and the fourth line portion 4 at the Y-direction ends of the first line portion 1, the second line portion 2, and the fourth line portion 4.

As illustrated in FIG. 1, the alignment mark M has a horizontal width W1 of 64 μm and a vertical width W2 of 18 μm, for example. Here, the horizontal width W1 denotes the dimension in the X direction in FIG. 1, and the vertical width W2 denotes the dimension in the Y direction. If the alignment mark M is the above size or greater, pattern recognition is easy when performing alignment according to an optical image in the CD-SEM, thereby mitigating the mistaken recognition of another pattern and improving the alignment accuracy.

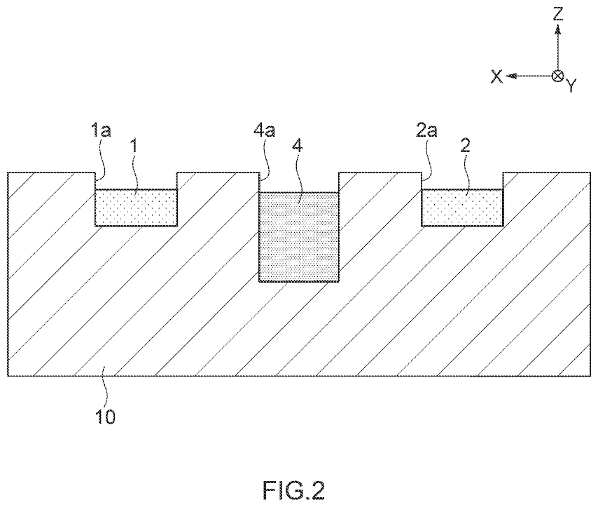

FIG. 2 is a longitudinal section illustrating an example of the structure of the alignment mark M. As illustrated in FIG. 2, the first line portion 1, the second line portion 2, and the fourth line portion 4 are provided respectively in a groove 1a, a groove 2a, and a groove 4a formed in a semiconductor substrate 10. The first line portion 1 and the second line portion 2 contain a conductive material, and for example, contain a high-melting-point metal such as tungsten (W) or titanium nitride (TiN). The fourth line portion 4 contains a material other than a metal, such as silicon dioxide (SiO₂), silicon nitride (SiN), or polysilicon (poly-Si), for example.

Note that, although not illustrated in FIG. 2, the third line portion 3 has the same structure as the first line portion 1 and the second line portion 2, as described above. Additionally, although not illustrated in FIG. 2, the semiconductor substrate 10 may also be provided with an insulating film covering the surfaces of first line portion 1, the second line portion 2, and the fourth line portion 4.

The first line portion 1 and the second line portion 2 are provided with a different material than the third line portion 3, and therefore have a different lightness, luminance, or color in an optical image. Consequently, the optical contrast ratio is increased between the first line portion 1 and the second line portion 2, and the third line portion 3. For this reason, pattern recognition is easy when performing alignment according to an optical image in the CD-SEM, thereby mitigating the mistaken recognition of another pattern and improving the alignment accuracy.

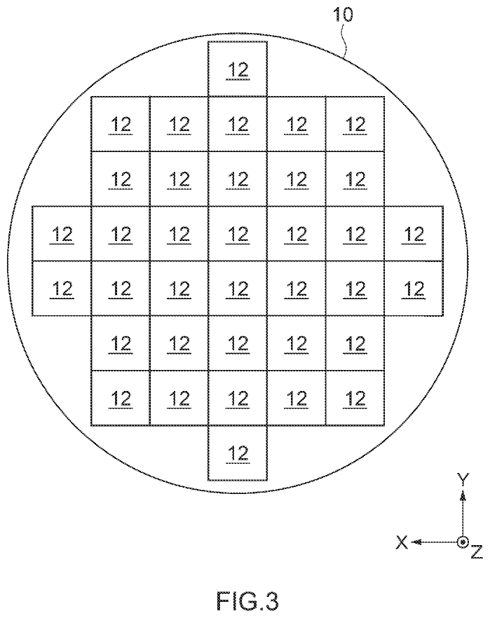

Next, the arrangement of the alignment mark M will be described. FIG. 3 illustrates an example of an arrangement of a plurality of shots 12 provided on the semiconductor substrate 10. As illustrated in FIG. 3, the shots 12 are arranged in a matrix on the semiconductor substrate 10. The shots 12 define rectangular sections. The shots 12 indicate semiconductor chips, and alignment patterns are arranged at a corner region of the shots 12, that is, the semiconductor chips.

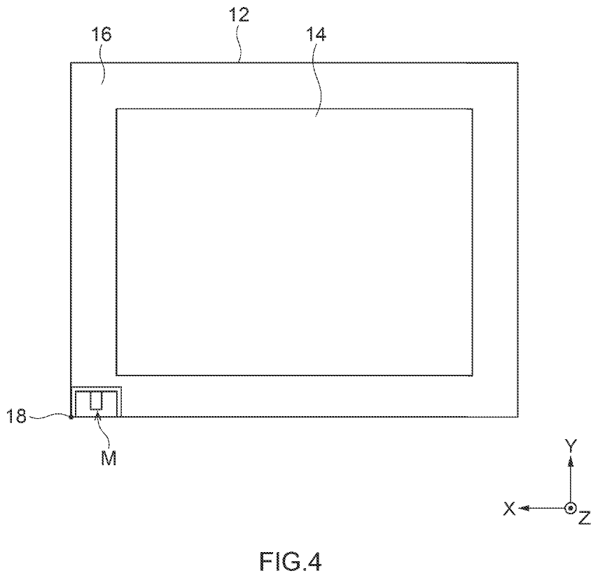

As illustrated in FIG. 4, each of the shots 12 is provided with an active region 14, a scribe region 16, and the alignment mark M. The active region 14 is provided with a rectangular shape of predetermined width and length. The scribe region 16 is disposed surrounding the active region 14. In the active region 14, an element such as a memory cell not illustrated is disposed, for example. In the scribe region 16, a test element not illustrated, an alignment mark for the exposure step, and the like are arranged, for example.

The alignment mark M is disposed in the scribe region 16. As illustrated in FIG. 4, the alignment mark M is disposed at a position located in the lower-left part in FIG. 4. The most lower-left point of the scribe region 16 is taken to be an origin 18. The alignment mark M is disposed so that the most lower-left part thereof is located at the origin 18.

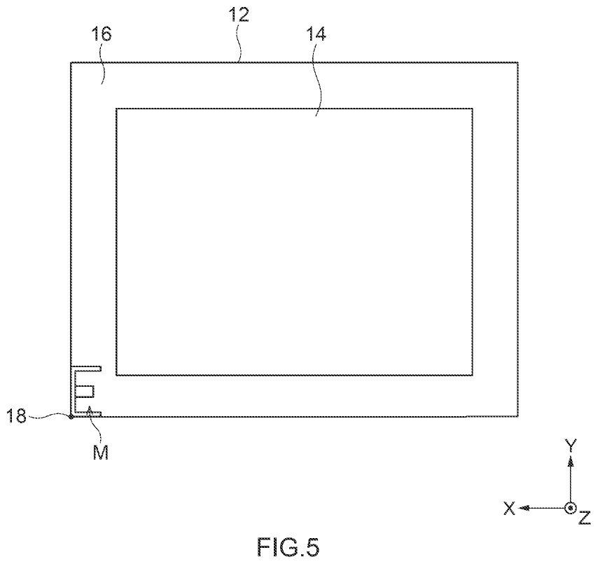

As illustrated in FIG. 5, the alignment mark M may be disposed in a state rotated 90 degrees to the left from the state illustrated in FIG. 1 or FIG. 4 in a planar view. In other words, the alignment mark M may be arranged in the orientation recognizable as an E shape in FIG. 5.

As described above, by configuring the alignment mark M into an E shape or an E shape rotated 90 degrees to the right in a planar view, the mistaken recognition of another pattern on the semiconductor substrate 10 can be mitigated during alignment by an optical image in the CD-SEM.

Moreover, the first line portion 1 and the second line portion 2 are provided with a different material than the third line portion 3, and therefore have a different lightness, luminance, or color in the optical image. Consequently, the optical contrast ratio is increased between the first line portion 1 and the second line portion 2, and the third line portion 3. This configuration can mitigate the mistaken recognition of another pattern on the semiconductor substrate 10. This configuration improves the accuracy of recognizing the location of the origin 18 of each shot 12 in the CD-SEM, thereby making it possible to confirm the length measurement location accurately.

The above describes an example of an alignment mark according to the embodiment with reference to the drawings, but the above is merely an example and is not intended to limit the disclosed form. The alignment mark according to the embodiment can be implemented in a memory device such as dynamic random access memory (DRAM), static random access memory (SRAM), flash memory, erasable programmable read-only memory (EPROM), magnetoresistive random-access memory (MRAM), and phase-change memory, for example. Furthermore, devices other than memory, including logic ICs such as a microprocessor and an application-specific integrated circuit (ASIC), for example, are also applicable as the semiconductor device according to the above embodiment.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising an alignment pattern which comprises:
a first line portion of a first material extending in a first direction;
a second line portion of the first material extending in the first direction in parallel to the first line portion;
a third line portion of the first material extending in a second direction perpendicular to the first direction such that the third line portion connects an edge of the first line portion and an edge of the second line portion; and
a fourth line portion of a second material arranged between the first line portion and the second line portion and extending in the first direction.

2. The apparatus of claim 1, wherein the apparatus is a semiconductor chip and the alignment pattern is arranged at a corner region of the semiconductor chip.

3. The apparatus of claim 1, wherein the first, second, third and fourth line portions are configured to form an E shape.

4. The apparatus of claim 1, wherein the first line portion and the second line portion have different widths than the fourth line portion.

5. The apparatus of claim 1, wherein each of the first line portion and the second line portion comprises a metal.

6. The apparatus of claim 1, wherein each of the first line portion and the second line portion includes at least one of W and TiN.

7. The apparatus of claim 1, wherein the fourth line portion comprises a material other than a metal.

8. The apparatus of claim 1, wherein the fourth line portion comprises at least one of silicon dioxide or silicon nitride.

9. An apparatus comprising an E-shaped alignment pattern at a corner thereof.

10. The apparatus of claim 9, wherein the E-shaped alignment pattern comprises:
a first line portion extending in a first direction;
a second line portion extending in the first direction in parallel to the first line portion;
a third line portion extending in a second direction perpendicular to the first direction such that the third line portion connects an edge of the first line portion and an edge of the second line portion; and
a fourth line portion arranged between the first line portion and the second line portion and extending in the first direction.

11. The apparatus of claim 10, wherein the first, second and third line portions comprise a first material and the fourth line portion comprises a second material different from the first material.

12. The apparatus of claim 10, wherein the first line portion, the second line portion, the third line portion and the fourth line portion have a rectangular shape.

13. The apparatus of claim 10, wherein the first line portion and the second line portion have different widths than the fourth line portion.

14. The apparatus of claim 10, wherein the first line portion and the second line portion comprise a metal.

15. The apparatus of claim 10, wherein the fourth line portion comprises a material other than a metal.

16. An apparatus comprising an alignment pattern which comprises:
a first line portion extending in a first direction;
a second line portion extending in the first direction in parallel to the first line portion;
a third line portion extending in a second direction perpendicular to the first direction such that the third line portion connects an edge of the first line portion and an edge of the second line portion; and
a fourth line portion arranged between the first line portion and the second line portion and extending in the first direction.

17. The apparatus of claim 16, wherein the first, second, and third line portions comprise a different material than the fourth line portion.

18. The apparatus of claim 16, wherein the first line portion and the second line portion comprise a metal; and
wherein the fourth line portion comprises a material other than a metal.
